(19) United States
(12) Patent Application Publication
(10) Pub. No.: US 2026/0334049 A1
(43) Pub. Date: Oct. 22, 2026

(54) DISPLAY DEVICE AND ELECTRONIC DEVICE INCLUDING THE DISPLAY DEVICE

(71) Applicant: Samsung Display Co., LTD., Yongin-si (KR)

(72) Inventor: Hyun Eok SHIN, Yongin-si (KR)

(21) Appl. No.: 19/386,777

(22) Filed: Nov. 12, 2025

(30) Foreign Application Priority Data
Apr. 21, 2025 (KR) 10-2025-0051458

(51) Int. Cl. H10K 59/80

(52) U.S. Cl. CPC H10K 59/80522

(57) ABSTRACT

A display device according to an embodiment comprises a substrate including a light emitting area and a non-light emitting area, a transistor located in the light emitting area, a first electrode electrically connected to the transistor, a light emitting layer located on the first electrode, a first auxiliary metal layer located on the light emitting layer and at an edge of the light emitting layer, a second auxiliary metal layer located on the first auxiliary metal layer, a spacer located between the first auxiliary metal layer and the second auxiliary metal layer, and a second electrode located on the light emitting layer and the second auxiliary metal layer.

This application claims priority to Korean Patent Application No. 10-2025-0051458 filed on Apr. 21, 2025, and all the benefits accruing therefrom under 35 U.S.C. §119, the content of which in its entirety is herein incorporated by reference.

### BACKGROUND

### 1. Field

The present disclosure relates to a display device and an electronic device including the display device.

### 2. Description of the Related Art

A light emitting display device (LED) includes a light emitting element including a hole injection electrode, an electron injection electrode, and a light emitting layer formed between the hole injection electrode and the electron injection electrode. An LED is a self-luminous display device in which holes injected from the hole injection electrode and electrons injected from the electron injection electrode combine in the light emitting layer to generate excitons that emit light when falling from an excited state to a ground state.

### SUMMARY

Embodiments are to provide a display device having a structure in which a second electrode is stably coupled through an auxiliary metal layer and an electronic device including the display device.

A display device according to an embodiment includes a substrate including a light emitting area and a non-light emitting area, a transistor located in the light emitting area, a first electrode electrically connected to the transistor, a light emitting layer located on the first electrode, a first auxiliary metal layer located on the light emitting layer and at an edge of the light emitting layer, a second auxiliary metal layer located on the first auxiliary metal layer, a spacer located between the first auxiliary metal layer and the second auxiliary metal layer, and a second electrode located on the light emitting layer and the second auxiliary metal layer.

An end of the second auxiliary metal layer may cover an edge of the light emitting layer.

An end of the spacer may cover an edge of the light emitting layer.

Ends of the first auxiliary metal layer may contact ends of the second auxiliary metal layer.

A portion of the spacer may be located between the first auxiliary metal layer and the second auxiliary metal layer.

The display device may further include an insulating layer located between the transistor and the first electrode, and another portion of the spacer may be located between the second auxiliary metal layer and the insulating layer.

The first auxiliary metal layer and the second auxiliary metal layer may include the same metal.

The first auxiliary metal layer and the second auxiliary metal layer may include titanium.

The spacer may include an inorganic insulating material.

The spacer may have a stepped shape toward the substrate in a cross-sectional view between adjacent first electrodes.

The second auxiliary metal layer may have a stepped shape toward the substrate in the cross-sectional view between the adjacent first electrodes.

The spacer may cover a side surface of the first auxiliary metal layer, a side surface of the light emitting layer, and a side surface of the first electrode.

A first end of the first auxiliary metal layer and a first end of the second auxiliary metal layer may be aligned with each other.

A first end of the light emitting layer and a second end of the first auxiliary metal layer may be aligned with each other.

In an electronic device including a display device according to an embodiment, the display device includes a substrate including a light emitting area and a non-light emitting area, a transistor located in the light emitting area, a first electrode electrically connected to the transistor, a light emitting layer located on the first electrode, a first auxiliary metal layer located on the light emitting layer, a second auxiliary metal layer located on the first auxiliary metal layer, and a second electrode located on the light emitting layer and the second auxiliary metal layer, wherein the second electrode contacts the first auxiliary metal layer and the second auxiliary metal layer.

A spacer located between the first auxiliary metal layer and the second auxiliary metal layer may be included.

The second electrode may contact a side surface of the first auxiliary metal layer, a side surface of the second auxiliary metal layer, and an upper surface of the second auxiliary metal layer.

An end of the first auxiliary metal layer and an end of the second auxiliary metal layer may contact each other.

The first auxiliary metal layer and the second auxiliary metal layer may include the same metal.

The second auxiliary metal layer may overlap with two adjacent first electrodes.

The present embodiments may provide a display device and an electronic device having improved reliability by enabling a stable form of second electrode using auxiliary metal layers.

### BRIEF DESCRIPTION OF THE DRAWINGS

FIG. 1 is a block diagram of an electronic device according to an embodiment.

FIG. 2 illustrates schematic diagrams of electronic devices according to various embodiments.

FIG. 3 is a schematic perspective view illustrating a use state of a display device according to an embodiment.

FIG. 4 is an exploded perspective view of a display device according to an embodiment.

FIG. 5 is a plan view illustrating a portion of a display area.

FIG. 6 is a cross-sectional view of a light emitting area and a non-light emitting area according to an embodiment.

FIG. 7 is a cross-sectional view of a light emitting layer according to an embodiment.

FIGS. 8-17 are cross-sectional views illustrating a method of manufacturing a display device according to an embodiment.

### DETAILED DESCRIPTION

Hereinafter, various embodiments of the present disclosure will be described in detail with reference to the accompanying drawings such that those skilled in the art can easily practice the present disclosure. The present disclosure can be implemented in various different forms and is not limited to the embodiments described herein.

To clearly describe the present disclosure, parts unrelated to the description have been omitted, and the same reference numerals are used for the same or similar components throughout the specification.

The size and thickness of each component illustrated in the drawings are arbitrarily illustrated for convenience of description, so the present disclosure is not necessarily limited to what is illustrated. In the drawings, the thickness is enlarged to clearly express various layers and regions. And in the drawings, for convenience of description, the thickness of some layers and regions is exaggerated.

For a case in which a part such as a layer, film, region, plate, and the like is said to be "on" or "over" another part, this includes not only the case where it is "directly on" another part but also the case where there is another part in between. Conversely, for a case in which a part is said to be "directly on" another part, it means that there is no other part in between. Being "on" or "over" a reference part means being located above or below the reference part, and does not necessarily mean being located "on" or "over" in the direction opposite to gravity. Throughout the specification, for a case in which a part is said to "include" a certain component, this means that it may further include other components rather than excluding other components unless specifically stated otherwise. Throughout the specification, "in a plan view" means the target part is viewed from above, and "in a cross-sectional view" means a cross section obtained by vertically cutting the target part is viewed from the side.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ± 30%, 20%, 10%, 5% of the stated value, for example.

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

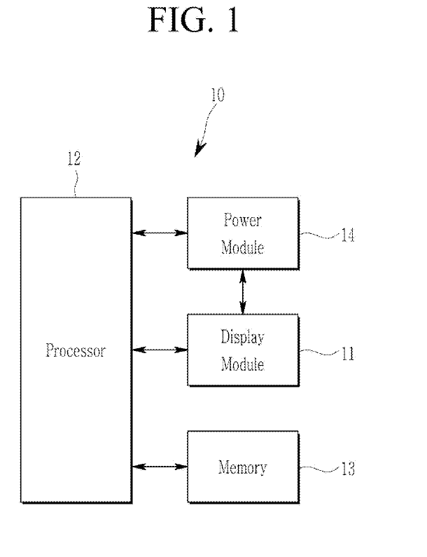

FIG. 1 is a block diagram of an electronic device according to an embodiment. Referring to FIG. 1, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information which is desirable for the operation of the processor 12 or the display module 11. For a case in which the processor 12 executes an application stored in the memory 13, image data signals and/or input control signals are transmitted to the display module 11, and the display module 11 processes the received signals to output image information through the display screen.

The power module 14 may include a power supply module such as, for example, a power adapter or battery device and a power conversion module that converts power supplied by the power supply module to generate power which is desirable for the operation of the electronic device 10.

At least one of the components of the electronic device 10 described herein may be included in a display device according to embodiments to be described later. In some aspects, among individual modules functionally included in one module, some may be included in the display device and others may be provided separately from the display device. For example, the display device may include the display module 11, and the processor 12, memory 13, and power module 14 may be provided in the form of other devices in the electronic device 10 rather than the display device.

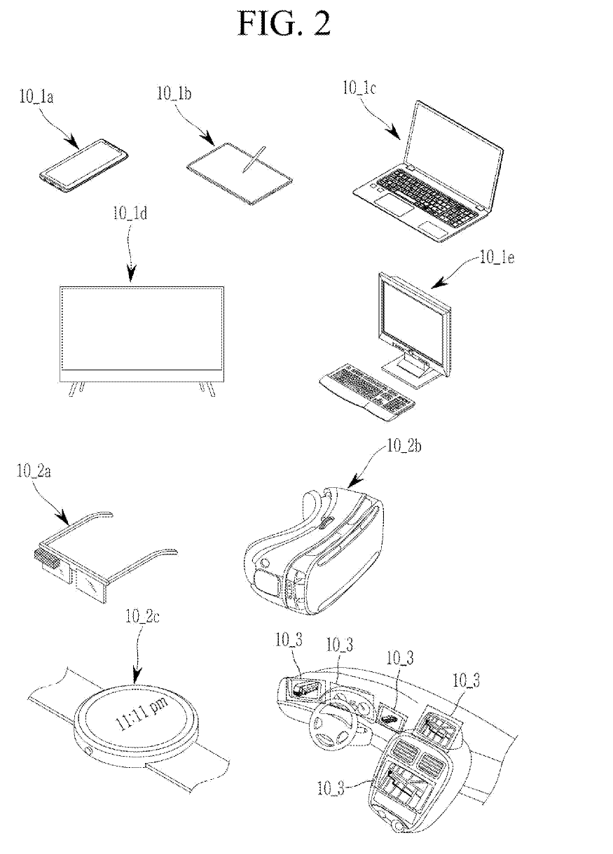

FIG. 2 illustrates schematic diagrams of electronic devices according to various embodiments.

Referring to FIG. 2, various electronic devices to which display devices according to embodiments are applied may include electronic devices for image display such as, for example, smartphones 10_1a, tablet PCs 10_1b, laptops 10_1c, TVs 10_1d, and desktop monitors 10_1e, as well as wearable electronic devices including display modules such as, for example, smart glasses 10_2a, head mounted displays 10_2b, and smart watches 10_2c, and vehicular electronic devices 10_3 including display modules such as, for example, automobile instrument panels, center fascias, center information displays (CID) disposed on dashboards, and room mirror displays.

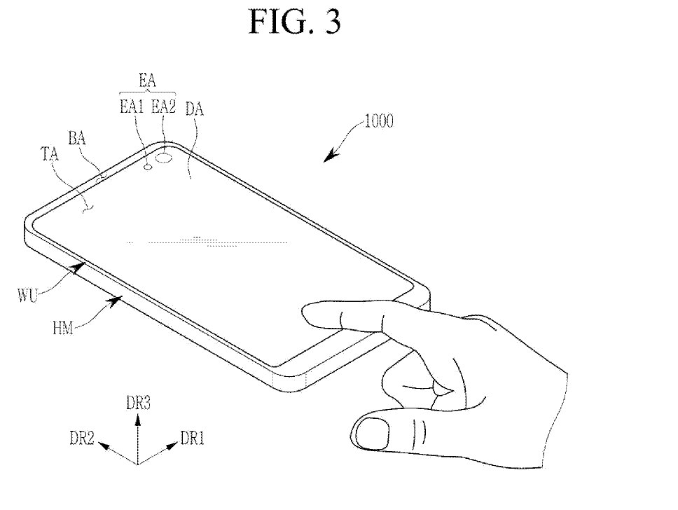

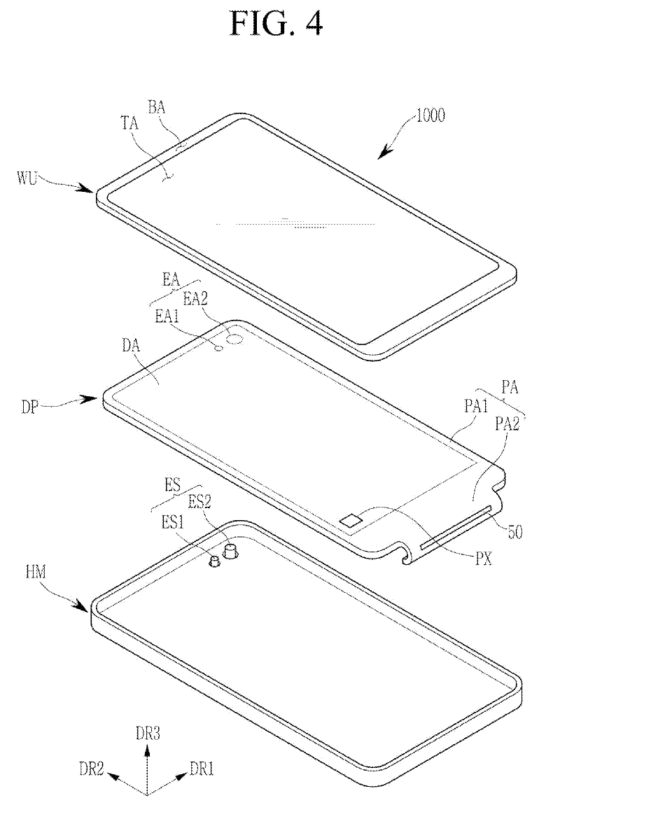

Hereinafter, a schematic structure of a display device will be described with reference to FIGS. 3 and 4. FIG. 3 is a schematic perspective view illustrating a use state of a display device according to an embodiment, and FIG. 4 is an exploded perspective view of a display device according to an embodiment.

FIG. 3 illustrates that the electronic device 1000 is used as a smartphone for convenience of description. The electronic device 1000 may display an image toward a third direction DR3 on a display surface parallel to each of a first direction DR1 and a second direction DR2. The display surface on which the image is displayed may correspond to a front surface of the electronic device 1000 and may correspond to a front surface of the cover window WU. The image may include a still image as well as a dynamic image.

In this embodiment, the front surface (or upper surface) and the rear surface (or lower surface) of each member are defined based on the direction in which an image is displayed. The front surface and the rear surface face each other in the third direction DR3, and the normal direction of each of the front surface and the rear surface may be parallel to the third direction DR3. The separation distance between the front surface and the rear surface in the third direction DR3 may correspond to the thickness of the display module in the third direction DR3.

The electronic device 1000 according to an embodiment may detect a user's input applied from the outside (see the hand in FIG. 3). The user's input may include various types of external inputs such as, for example, a part of the user's body, light, heat, or pressure. In an embodiment, the user's input is illustrated as the user's hand applied to the front surface. However, embodiments of the present disclosure are not limited thereto. The user's input may be provided in various forms, and the electronic device 1000 may also detect the user's input applied to the side or rear surface of the electronic device 1000 according to the structure of the electronic device 1000.

Referring to FIGS. 3 and 4, the electronic device 1000 may include a cover window WU, a housing HM, a display module DP, and an optical element ES. In an embodiment, the cover window WU and the housing HM may be combined to form the exterior of the electronic device 1000.

The cover window WU may include an insulating panel. For example, the cover window WU may be formed of glass, plastic, or a combination thereof.

The front surface of the cover window WU may define the front surface of the electronic device 1000. The transmission area TA may be an optically transparent area. For example, the transmission area TA may be an area having a visible light transmittance of about 90% or more.

The blocking area BA may define the shape of the transmission area TA. The blocking area BA is adjacent to the transmission area TA and may surround the transmission area TA. The blocking area BA may be an area having relatively lower light transmittance than the transmission area TA. The blocking area BA may include an opaque material that blocks light. The blocking area BA may have a predetermined color. The blocking area BA may be defined by a bezel layer provided separately from the transparent substrate defining the transmission area TA, or may be defined by an ink layer formed by being inserted or colored in the transparent substrate.

The display module DP may include pixels PX displaying an image and a driver 50, and the pixels PX are located in the display area DA and the component area EA. The display module DP may include a front surface including the display area DA and the non-display area PA. In an embodiment, the display area DA and the component area EA are areas where an image is displayed including pixels, and at the same time, may be areas where external input is detected by a touch sensor located on the upper side in the third direction DR3 of the pixels.

The transmission area TA of the cover window WU may at least partially overlap with the display area DA and the component area EA of the display module DP. For example, the transmission area TA may overlap with the front surface of the display area DA and the component area EA, or may overlap with at least a portion of the display area DA and the component area EA. Accordingly, the user can view an image through the transmission area TA or provide external input based on the image. However, embodiments of the present disclosure are not limited thereto. For example, the area where the image is displayed and the area where the external input is detected may be separated from each other.

The non-display area PA of the display module DP may at least partially overlap with the blocking area BA of the cover window WU. The non-display area PA may be an area covered by the blocking area BA. The non-display area PA is adjacent to the display area DA and may surround the display area DA. The non-display area PA does not display an image, and driving circuits or driving wires for driving the display area DA may be disposed therein. The non-display area PA may include a first peripheral area PA1 where the display area DA is located on the outside and a second peripheral area PA2 including the driver 50, connection wiring, and a bending area. In the embodiment of FIG. 4, the first peripheral area PA1 is located on three sides of the display area DA, and the second peripheral area PA2 is located on the remaining one side of the display area DA.

In an embodiment, the display module DP may be assembled in a flat state with the display area DA, the component area EA, and the non-display area PA facing the cover window WU. Alternatively, according to embodiments, a portion of the non-display area PA of the display module DP may be curved. At this time, a portion of the non-display area PA faces the rear surface of the electronic device 1000, such that the blocking area BA visible on the front surface of the electronic device 1000 may be reduced, and in FIG. 4, the second peripheral area PA2 may be bent and positioned on the rear surface of the display area DA before assembly. In some aspects, the component area EA of the display module DP may include a first component area EA1 and a second component area EA2. The first component area EA1 and the second component area EA2 may be at least partially surrounded by the display area DA. The first component area EA1 and the second component area EA2 are illustrated as being spaced apart from each other, but are not limited thereto and may be at least partially connected. The first component area EA1 and the second component area EA2 may be areas where optical elements (see ES in FIG. 4; hereinafter also referred to as components) using infrared rays, visible light, or sound are disposed below.

The display area DA (hereinafter also referred to as a main display area) and the component area EA are formed with a plurality of light emitting diodes and a plurality of pixel circuit units that generate and transmit a light emitting current to each of the plurality of light emitting diodes. Here, one light emitting diode and one pixel circuit unit are referred to as a pixel PX. In the display area DA and the component area EA, one pixel circuit unit and one light emitting diode may be formed in a one-to-one manner.

The first component area EA1 may include a transmission part through which light and/or sound can pass and a display part including a plurality of pixels. The transmission part is located between adjacent pixels and includes a layer through which light and/or sound can pass. The transmission part may be located between adjacent pixels, and according to embodiments, a layer through which light does not pass, such as a light blocking member, may overlap with the first component area EA1. The number of pixels per unit area (hereinafter also referred to as resolution) of pixels (hereinafter also referred to as normal pixels) included in the display area DA and the number of pixels per unit area of pixels (hereinafter also referred to as first component pixels) included in the first component area EA1 may be the same.

The second component area EA2 includes an area (hereinafter also referred to as a light transmission area) including a transparent layer for transmitting light, and the light transmission area does not have a conductive layer or a semiconductor layer positioned therein, and may have a structure that does not block light by including a layer including a light blocking material, for example, a pixel definition layer and/or a light blocking member having an opening overlapping with a position corresponding to the second component area EA2. The number of pixels per unit area of pixels (hereinafter also referred to as second component pixels) included in the second component area EA2 may be smaller than the number of pixels per unit area of normal pixels included in the display area DA. As a result, the resolution of the second component pixels may be lower than the resolution of the normal pixels.

The second peripheral area PA2 may include a bending portion. The display area DA and the first peripheral area PA1 may have a flat state substantially parallel to a plane defined by the first direction DR1 and the second direction DR2, and a side of the second peripheral area PA2 may extend from the flat state, pass through the bending portion, and then have a flat state again. As a result, at least a portion of the second peripheral area PA2 may be bent and assembled to be positioned on the rear side of the display area DA. For a case in which at least a portion of the second peripheral area PA2 is assembled, the portion of the second peripheral area PA2 may overlap with the display area DA in a plane, such that the blocking area BA of the electronic device 1000 may be reduced. However, embodiments of the present disclosure are not limited thereto. For example, the second peripheral area PA2 may not be bent.

The driver 50 may be mounted on the second peripheral area PA2, and may be mounted on the bending portion or located on one of both sides of the bending portion. The driver 50 may be provided in a chip form.

The driver 50 may be electrically connected to the display area DA and the component area EA to transmit electrical signals to the pixels of the display area DA and the component area EA. For example, the driver 50 may provide data signals to the pixels PX disposed in the display area DA. Alternatively, the driver 50 may include a touch driving circuit and may be electrically connected to the touch sensor TS disposed in the display area DA and/or the component area EA. In some aspects, the driver 50 may be designed to include various circuits in addition to the above-described circuits or to provide various electrical signals to the display area DA.

In some aspects, the electronic device 1000 may have a pad portion located at an end of the second peripheral area PA2, and may be electrically connected to a flexible printed circuit board (FPCB) including a driving chip through the pad portion. Here, the driving chip located on the flexible printed circuit board may include various driving circuits for driving the electronic device 1000, connectors for power supply, and the like. According to embodiments, a rigid printed circuit board (PCB) may be used instead of the flexible printed circuit board.

The optical element ES may be disposed below the display module DP. The optical element ES may include a first optical element ES1 overlapping the first component area EA1 and a second optical element ES2 overlapping the second component area EA2. The first optical element ES1 may use infrared rays, and in this case, a layer through which light does not pass, such as a light blocking member, may overlap with the first component area EA1.

The first optical element ES1 may be an electronic element using light or sound. For example, the first optical element ES1 may be a sensor that receives and uses light such as, for example, an infrared sensor, a sensor that outputs and senses light or sound to measure distance or recognize fingerprints, a small lamp that outputs light, or a speaker that outputs sound. In the case of electronic elements using light, embodiments of the present disclosure may support the use of light of various wavelength bands such as, for example, visible light, infrared light, and ultraviolet light.

The second optical element ES2 may be at least one of a camera, an infrared camera (IR camera), a dot projector, an infrared illuminator (IR illuminator), and a time-of-flight sensor (ToF sensor).

The housing HM may be coupled with the cover window WU. The cover window WU may be disposed on the front surface of the housing HM. The housing HM may be coupled with the cover window WU to provide an accommodation space. The display module DP and the optical element ES may be accommodated in the accommodation space provided between the housing HM and the cover window WU.

The housing HM may include a material having relatively high rigidity. For example, the housing HM may include glass, plastic, or metal, or may include a plurality of frames and/or plates including a combination thereof. The housing HM may stably protect the components of the electronic device 1000 accommodated in the internal space from external impacts.

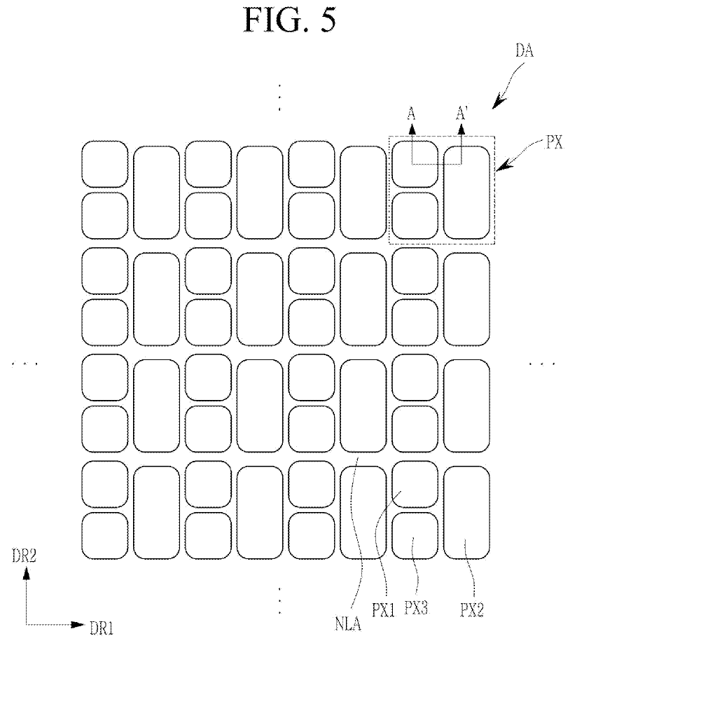

Hereinafter, with reference to FIG. 5, pixels PX disposed in the display area DA according to an embodiment will be described. FIG. 5 is a plan view illustrating a portion of the display area DA.

A display device according to an embodiment may include pixels PX disposed in the display area DA. The pixel PX may include a first light emitting area PX1, a second light emitting area PX2, and a third light emitting area PX3 that display different colors. For example, the pixel PX may include a first light emitting area PX1 emitting red light, a second light emitting area PX2 emitting blue light, and a third light emitting area PX3 emitting green light.

This specification illustrates an embodiment in which each of the first light emitting area PX1, the second light emitting area PX2, and the third light emitting area PX3 has a quadrangular shape, but is not limited thereto, and each light emitting area may be variously changed to a circle, an ellipse, a polygon, a polygon with rounded corners, or the like.

The first light emitting area PX1, the second light emitting area PX2, and the third light emitting area PX3 may be repeatedly arranged along the first direction DR1 and the second direction DR2. For example, as illustrated in FIG. 5, the first light emitting area PX1 and the second light emitting area PX2 may be alternately arranged along the first direction DR1, and the third light emitting area PX3 and the second light emitting area PX2 may be alternately arranged along the first direction DR1. In some aspects, the first light emitting area PX1 and the third light emitting area PX3 may be alternately arranged in a column along the second direction DR2, and the second light emitting area PX2 may be repeatedly arranged in another column adjacent to the column. The arrangement form of the pixels is not limited to this arrangement form, and the first light emitting area PX1, the second light emitting area PX2, and the third light emitting area PX3 may be arranged in various forms.

A display device according to an embodiment may include a non-light emitting area NLA that does not overlap with the first light emitting area PX1, the second light emitting area PX2, and the third light emitting area PX3 in the display area DA. The non-light emitting area NLA is disposed to be spaced apart from the first light emitting area PX1, the second light emitting area PX2, and the third light emitting area PX3. The non-light emitting area NLA may be disposed between adjacent first light emitting area PX1, second light emitting area PX2, and third light emitting area PX3.

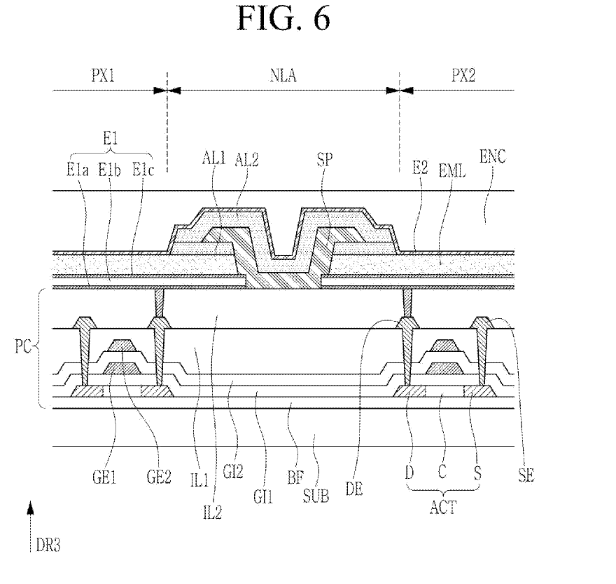

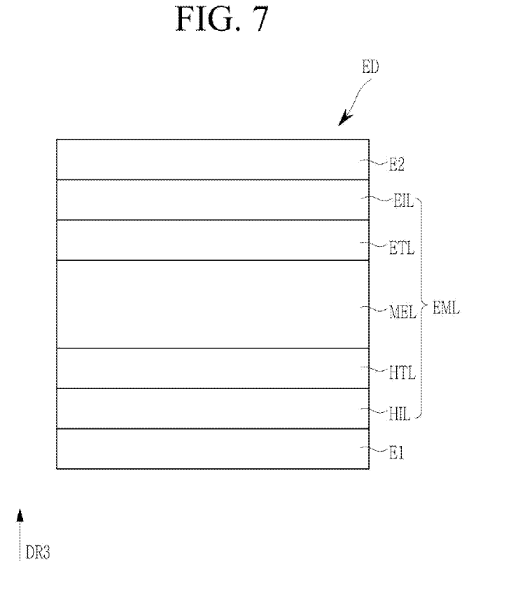

Hereinafter, with reference to FIGS. 6 and 7, a stacked structure of a light emitting area and a non-light emitting area according to an embodiment will be described. FIG. 6 is a cross-sectional view of a light emitting area and a non-light emitting area according to an embodiment. FIG. 7 is a cross-sectional view of a light emitting layer according to an embodiment.

First, referring to FIG. 6, the substrate SUB may include a material having rigid characteristics such as, for example, glass or a flexible material that may be bent such as, for example, plastic or polyimide. Referring to FIG. 5 together with FIG. 6, the substrate SUB may include a light emitting area including a first light emitting area PX1, a second light emitting area PX2, and a third light emitting area PX3, and a non-light emitting area NLA located between the light emitting areas PX1, PX2, PX3.

Referring again to FIG. 6, a buffer layer BF may be located on the substrate SUB. The buffer layer BF may include an inorganic material, and for example, may include an inorganic insulating material such as, for example, silicon nitride (SiNx), silicon oxide (SiOx), or silicon oxynitride (SiOxNy). According to embodiments, the buffer layer BF may have a single-layer or multi-layer structure including the above inorganic insulating material.

A semiconductor layer ACT may be located on the buffer layer BF. The semiconductor layer ACT may include any one of amorphous silicon, polycrystalline silicon, and an oxide semiconductor. For example, the semiconductor layer ACT may include low temperature polysilicon (LTPS) or may include an oxide semiconductor including at least one of zinc (Zn), indium (In), gallium (Ga), tin (Sn), and mixtures thereof. For example, the semiconductor layer ACT may include Indium-Gallium-Zinc Oxide (IGZO).

The semiconductor layer ACT may include a channel region C, a source region S, and a drain region D that are distinguished according to whether or not impurities are doped. The source region S and the drain region D may be located on both sides of the channel region C. The source region S and the drain region D doped with impurities may have conductive characteristics corresponding to conductors.

A first gate insulating layer GI1 may be located on the semiconductor layer ACT. The first gate insulating layer GI1 may cover the semiconductor layer ACT and the substrate SUB. The first gate insulating layer GI1 may include an inorganic insulating material such as, for example, silicon nitride (SiNx), silicon oxide (SiOx), or silicon oxynitride (SiOxNy). The first gate insulating layer GI1 may have a single-layer or multi-layer structure including the above inorganic insulating material.

A gate electrode GE1 may be located on the first gate insulating layer GI1. The gate electrode GE1 may include a metal or metal alloy such as, for example, copper (Cu), molybdenum (Mo), aluminum (Al), silver (Ag), chromium (Cr), tantalum (Ta), or titanium (Ti). The gate electrode GE1 may include a single layer or multiple layers. A region of the semiconductor layer ACT overlapping with the gate electrode GE1 may be the channel region C.

A second gate insulating layer GI2 may be located on the gate electrode GE1. The second gate insulating layer GI2 may cover the gate electrode GE1 and the first gate insulating layer GI1. The second gate insulating layer GI2 may overlap with most of the substrate SUB. The second gate insulating layer GI2 may include an inorganic insulating material such as, for example, silicon nitride (SiNx), silicon oxide (SiOx), or silicon oxynitride (SiOxNy). The second gate insulating layer GI2 may have a single-layer or multi-layer structure including the above inorganic insulating material.

A capacitor electrode GE2 may be located on the second gate insulating layer GI2. The capacitor electrode GE2 may overlap with the gate electrode GE1 to form a capacitor. The capacitor electrode GE2 may include a metal or metal alloy such as, for example, copper (Cu), molybdenum (Mo), aluminum (Al), silver (Ag), chromium (Cr), tantalum (Ta), or titanium (Ti). The capacitor electrode GE2 may include a single layer or multiple layers.

A first insulating layer IL1 may be located on the capacitor electrode GE2. The first insulating layer IL1 may include an inorganic insulating material such as, for example, silicon nitride (SiNx), silicon oxide (SiOx), or silicon oxynitride (SiOxNy). The first insulating layer IL1 may have a single-layer or multi-layer structure including the above inorganic insulating material.

A source electrode SE and a drain electrode DE may be located on the first insulating layer IL1. The source electrode SE and the drain electrode DE are electrically connected to the source region S and the drain region D of the semiconductor layer ACT, respectively, through openings defined in the first insulating layer IL1, the second gate insulating layer GI2, and the first gate insulating layer GI1.

The above-described semiconductor layer ACT, gate electrode GE1, source electrode SE, and drain electrode DE form a transistor. According to embodiments, the transistor may include the source region and the drain region of the semiconductor layer ACT instead of the source electrode SE and the drain electrode DE.

The source electrode SE and the drain electrode DE may include a metal or metal alloy such as, for example, aluminum (Al), copper (Cu), silver (Ag), gold (Au), platinum (Pt), palladium (Pd), nickel (Ni), molybdenum (Mo), tungsten (W), titanium (Ti), chromium (Cr), or tantalum (Ta). The source electrode SE and the drain electrode DE may include a single layer or multiple layers. The source electrode SE and the drain electrode DE according to an embodiment may include a triple layer including an upper layer, a middle layer, and a lower layer, where the upper layer and the lower layer may include titanium (Ti), and the middle layer may include aluminum (Al).

A second insulating layer IL2 may be located on the source electrode SE and the drain electrode DE. The second insulating layer IL2 may cover the source electrode SE, the drain electrode DE, and the first insulating layer IL1. The second insulating layer IL2 is for planarizing the surface of the substrate SUB on which the transistor is provided, and may be an organic insulating layer, and may include one or more materials selected from the group including polyimide, polyamide, acrylic resin, benzocyclobutene, and phenol resin.

A first electrode E1 may be located on the second insulating layer IL2. The first electrode E1, also referred to as an anode electrode, may include a single layer or multiple layers including a transparent conductive oxide layer or a metal material. The transparent conductive oxide layer may include Indium Tin Oxide (ITO), poly-ITO, Indium Zinc Oxide (IZO), Indium Gallium Zinc Oxide (IGZO), and Indium Tin Zinc Oxide (ITZO). The metal material may include at least one of silver (Ag) and aluminum (Al). For example, the first electrode E1 may include a first layer E1a including ITO, a second layer E1b including Ag, and a third layer E1c including ITO, but is not limited thereto.

The center of the first electrode E1 may overlap with the first light emitting area PX1 and the second light emitting area PX2, and the edge of the first electrode E1 may overlap with the non-light emitting area NLA.

The first electrode E1 may be physically and electrically connected to the drain electrode DE through an opening of the second insulating layer IL2. Accordingly, the first electrode E1 may receive an output current to be transmitted from the drain electrode DE to a light emitting layer EML to be described later.

A light emitting layer EML may be located on the first electrode E1. The light emitting layer EML may overlap with the center of the first electrode E1 and may not overlap with the edge of the first electrode E1. The side surface of the light emitting layer EML may have a high inclination in cross-section, for example, may form an inclination angle of 70° to 90°, or about 90° with the substrate SUB.

The light emitting layer EML may include organic or inorganic materials that emit light such as, for example, red, green, and blue. The light emitting layer EML that emits red, green, and blue light may include low molecular weight or high molecular weight organic materials. According to embodiments, the light emitting layer EML may include quantum dots. Quantum dots (also referred to as semiconductor nanocrystals) may include II-VI group compounds, III-V group compounds, IV-VI group compounds, group IV elements or compounds, I-III-VI group compounds, II-III-VI group compounds, I-II-IV-VI group compounds, or combinations thereof. The quantum dots may not include cadmium.

The light emitting layer EML may overlap with the first light emitting area PX1, the second light emitting area PX2, and the third light emitting area PX3, respectively. A display device according to an embodiment may include a first light emitting layer overlapping the first light emitting area PX1, a second light emitting layer overlapping the second light emitting area PX2, and a third light emitting layer overlapping the third light emitting area PX3. For example, the first light emitting layer may emit red light, the second light emitting layer may emit blue light, and the third light emitting layer may emit green light.

Each of the light emitting layers EML according to an embodiment may be individually patterned. For example, a first light emitting material layer may be applied and then patterned to form a first light emitting layer, a second light emitting material layer may be applied and then patterned to form a second light emitting layer, and a third light emitting material layer may be applied and then patterned to form a third light emitting layer.

In some aspects, referring to FIG. 7, one light emitting layer EML may include auxiliary layers including an electron injection layer EIL, an electron transport layer ETL, a hole transport layer HTL, and a hole injection layer HIL, and a main light emitting layer MEL. For example, the first light emitting layer may include a first hole injection layer, a first hole transport layer, a first main light emitting layer, a first electron transport layer, and a first electron injection layer. The second light emitting layer may include a second hole injection layer, a second hole transport layer, a second main light emitting layer, a second electron transport layer, and a second electron injection layer. The third light emitting layer may include a third hole injection layer, a third hole transport layer, a third main light emitting layer, a third electron transport layer, and a third electron injection layer. Each of the first main light emitting layer, the second main light emitting layer, and the third main light emitting layer may include different materials.

The light emitting layer EML may include at least one of a triphenylamine-based compound, carbazole, an aromatic amine-based compound, an anthracene-based compound, hydroxyquinoline, and an iridium complex. For example, the main light emitting layer MEL may include at least one of an anthracene-based compound, a triphenylamine-based compound, and an iridium complex. The hole injection layer HIL and the hole transport layer HTL may include at least one of a triphenylamine-based compound and carbazole, the electron transport layer ETL may include at least one of an anthracene-based compound and an aromatic amine-based compound, and the electron injection layer EIL may include hydroxyquinoline.

A second electrode E2 may be located on the light emitting layer EML. The second electrode E2, also referred to as a cathode electrode, may be a single layer or multiple layers including a transparent conductive layer, and may include at least one of Indium Tin Oxide (ITO), Indium Zinc Oxide (IZO), Indium Gallium Zinc Oxide (IGZO), and Indium Tin Zinc Oxide (ITZO). In some aspects, the second electrode E2 may have translucent characteristics, in which case the second electrode E2 may form a micro-cavity together with the first electrode E1. According to the micro-cavity structure, light of a specific wavelength is emitted upward due to the spacing and characteristics between the two electrodes, and as a result, red, green, or blue can be displayed. The first electrode E1, the light emitting layer EML, and the second electrode E2 may form one light emitting element ED.

Referring back to FIG. 6, an encapsulation layer ENC may be located on the second electrode E2. The encapsulation layer ENC may include at least one inorganic layer and at least one organic layer.

In the non-light emitting area NLA located between adjacent light emitting areas PX1 and PX2, a first auxiliary metal layer AL1 may be located on the light emitting layer EML. The first auxiliary metal layer AL1 may be located on the light emitting layer EML located in the first light emitting area PX1. In some aspects, the first auxiliary metal layer AL1 may be located on the light emitting layer EML located in the second light emitting area PX2. The first auxiliary metal layer AL1 may be located on a light emitting layer located in the third light emitting area PX3, although not illustrated. The first auxiliary metal layers AL1 located on different light emitting layers may be spaced apart from each other.

The first auxiliary metal layer AL1 may overlap with the non-light emitting area NLA and may be spaced apart from the light emitting areas PX1 and PX2. An end of the first auxiliary metal layer AL1 may be aligned with the light emitting layer EML, and the other end of the first auxiliary metal layer AL1 may be aligned with the second auxiliary metal layer AL2. That is, the end of the first auxiliary metal layer AL1 may form a side surface having the same inclination as an end of the light emitting layer EML. The other end of the first auxiliary metal layer AL1 may form a side surface having the same inclination as an end of the second auxiliary metal layer AL2.

The first auxiliary metal layer AL1 may include a metal, and for example, may include titanium (Ti). The first auxiliary metal layer AL1 formed of titanium may have excellent adhesion with a second auxiliary metal layer AL2 to be described later. In some aspects, even for a case in which the first auxiliary metal layer AL1 is exposed to an etching solution during the manufacturing process, the first auxiliary metal layer AL1 has excellent resistance to the etching solution and may be provided in a stable form.

A spacer SP may be located in the non-light emitting area NLA. The spacer SP may be located between adjacent light emitting areas PX1 and PX2. The spacer SP may be located between the first light emitting area PX1 and the second light emitting area PX2 as illustrated in FIG. 6. The spacer SP physically separates the first light emitting layer EML1 and the second light emitting layer EML2 and provides electrical insulation, preventing problems such as, for example, current leakage.

The spacer SP may include an inorganic insulating material. The spacer SP may include, for example, at least one of silicon nitride, silicon oxide, and silicon oxynitride.

The spacer SP may be located on a portion of the first auxiliary metal layer AL1. The spacer SP may cover a portion of the upper surface of the first auxiliary metal layer AL1, a side surface of the first auxiliary metal layer AL1, a side surface of the light emitting layer EML, and a side surface of the first electrode E1. The spacer SP may also include a flat portion connected to the portion of the spacer SP located in the adjacent light emitting area PX2. The spacer SP may be located along the steps of the first auxiliary metal layer AL1, the light emitting layer EML, and the first electrode E1. The spacer SP may have a recessed shape toward the substrate SUB in the non-light emitting area NLA in cross section.

The spacer SP may have substantially the same thickness in the non-light emitting area NLA. The thickness of the spacer SP may be about 1000 angstroms to about 3000 angstroms, for example, about 2000 angstroms.

The spacer SP may overlap with an edge of the first electrode E1, an edge of the light emitting layer EML, and an edge of the first auxiliary metal layer AL1. The spacer SP may provide electrical insulation by covering the ends of the first electrode E1 and the light emitting layer EML.

The spacer SP may overlap with two light emitting layers EML located in adjacent light emitting areas PX1 and PX2. In some aspects, the spacer SP may overlap with two first electrodes E1 located in adjacent light emitting areas PX1 and PX2. In some aspects, the spacer SP may overlap with each first auxiliary metal layer AL1 located in adjacent light emitting areas PX1 and PX2.

In the non-light emitting area NLA, a second auxiliary metal layer AL2 may be located on the spacer SP. The second auxiliary metal layer AL2 may contact the first auxiliary metal layer AL1 exposed by the spacer SP. The first auxiliary metal layer AL1 and the second auxiliary metal layer AL2 may bring about stable bonding by contacting each other. In some aspects, resistance may be reduced by the second electrode E2 contacting the first auxiliary metal layer AL1 and the second auxiliary metal layer AL2.

A portion of the second auxiliary metal layer AL2 may overlap with a portion of the first auxiliary metal layer AL1, a portion of the light emitting layer EML, and a portion of the first electrode E1. A portion of the second auxiliary metal layer AL2 may overlap with an edge of the first auxiliary metal layer AL1, an edge of the light emitting layer EML, and an edge of the first electrode E1.

The second auxiliary metal layer AL2 may be located along the upper surface of the spacer SP. The second auxiliary metal layer AL2 may completely cover the upper surface and side surfaces of the spacer SP. The second auxiliary metal layer AL2 may be disposed along the step of the spacer SP. The second auxiliary metal layer AL2 may have a recessed shape toward the substrate SUB in cross section in the non-light emitting area NLA, similar to the spacer SP. The spacer SP may be disposed between the second auxiliary metal layer AL2 and the first auxiliary metal layer AL1.

The second auxiliary metal layer AL2 may include a metal, and may include the same metal as the first auxiliary metal layer AL1. The second auxiliary metal layer AL2 may include, for example, titanium (Ti), and may have excellent adhesion with the first auxiliary metal layer AL1.

The thickness of the second auxiliary metal layer AL2 may be substantially the same as the thickness of the first auxiliary metal layer AL1. For example, the thickness of each of the first auxiliary metal layer AL1 and the second auxiliary metal layer AL2 may be 2000 angstroms.

Ends of the first auxiliary metal layer AL1 and ends of the second auxiliary metal layer AL2 may be aligned with each other. For example, an end of the first auxiliary metal layer AL1 and an end of the second auxiliary metal layer AL2 may provide a tapered inclined surface, and the inclined surface may be one substantially flat inclined surface. Because an undercut or the like is not formed, the second electrode E2 disposed on the second auxiliary metal layer AL2 may be stably disposed.

A second electrode E2 may be located on the light emitting layer EML and the second auxiliary metal layer AL2. The second electrode E2 may have a shape overlapping the entire surface of the substrate SUB. The second electrode E2 may be continuously disposed over the light emitting areas PX1 and PX2 and the non-light emitting area NLA. The second electrode E2 may contact a side surface of the first auxiliary metal layer AL1, a side surface of the second auxiliary metal layer AL2, and an upper surface of the second auxiliary metal layer AL2. The second electrode E2 stably contacts the first auxiliary metal layer AL1 and the second auxiliary metal layer AL2, such that disconnection of the second electrode E2 does not occur. Therefore, problems such as, for example, current leakage or driving errors can be prevented.

In some aspects, although FIG. 6 illustrates and describes cross sections of the first light emitting area PX1 and the second light emitting area PX2, embodiments of the present disclosure are not limited thereto and can of course be applied to the above-described third light emitting area PX3.

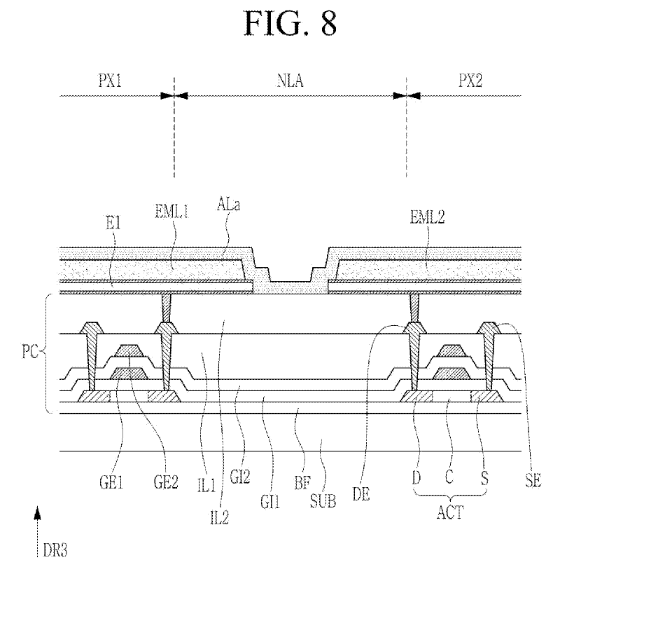

Hereinafter, a method of manufacturing a display device according to an embodiment will be described with reference to FIGS. 8-17. Each of FIGS. 8-17 is a cross-sectional view illustrating a method of manufacturing a display device according to an embodiment.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

First, referring to FIG. 8, a circuit portion PC including a transistor is formed on a substrate SUB. Then, a first electrode E1 is formed on the circuit portion PC. Next, a first light emitting layer EML1 is formed in the first light emitting area PX1, and a second light emitting layer EML2 is formed in the second light emitting area PX2. The light emitting layers EML1 and EML2 according to an embodiment may be provided through respective patterning processes.

Next, a first metal material layer ALa may be formed to overlap the entire surface of the substrate SUB. The first metal material layer ALa may be continuously disposed over the first light emitting area PX1, the non-light emitting area NLA, and the second light emitting area PX2. In some aspects, although not illustrated in FIG. 8, the first metal material layer ALa may also be formed in the third light emitting area.

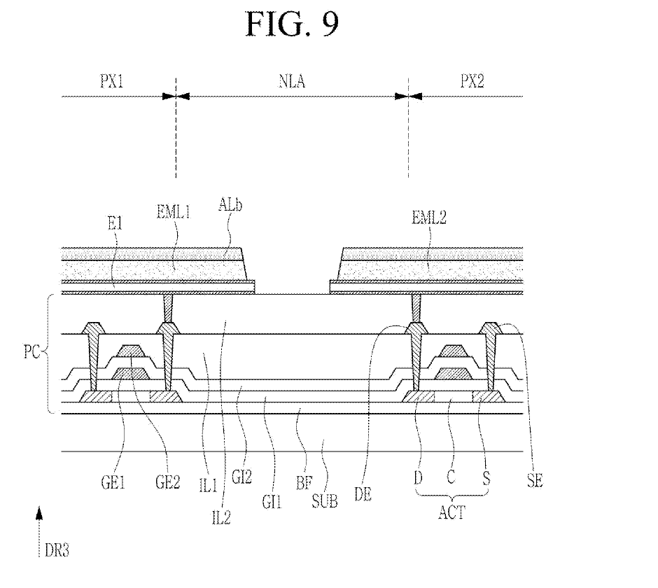

Next, as illustrated in FIG. 9, a second metal material layer ALb may be formed. The second metal material layer ALb may be formed by patterning the first metal material layer ALa of FIG. 8. The second metal material layer ALb may be located on the first light emitting layer EML1 or may be located on the second light emitting layer EML2. Although not illustrated in FIG. 8, the second metal material layer ALb may be located on a third light emitting layer disposed in the third light emitting area. Each of the second metal material layers ALb spaced apart from each other may overlap with the first electrode E1 and the light emitting layer EML located in the corresponding light emitting areas PX1 and PX2.

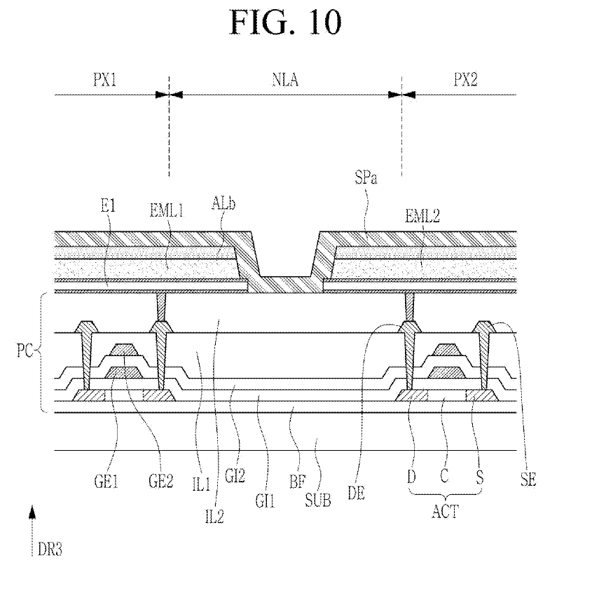

Then, as illustrated in FIG. 10, an insulating material layer SPa may be formed on the entire surface of the substrate SUB. The insulating material layer SPa may be continuously formed over the first light emitting area PX1, the second light emitting area PX2, the third light emitting area, and the non-light emitting area NLA. The insulating material layer SPa may include an inorganic insulating material. The inorganic insulating material may include silicon nitride, silicon oxide, silicon oxynitride, and the like.

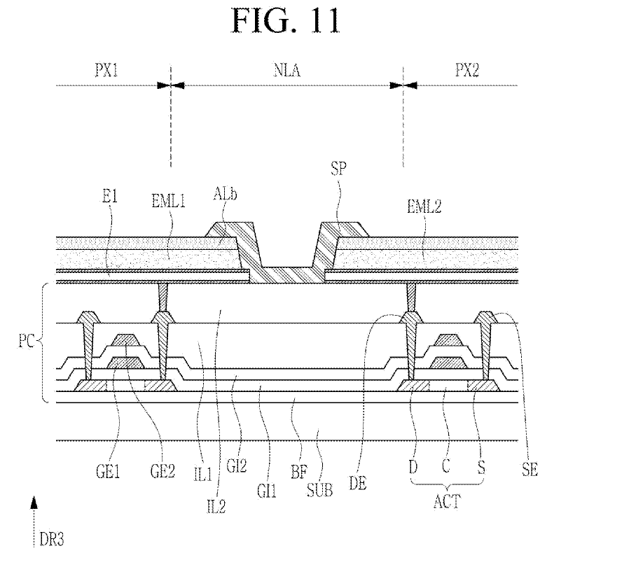

The insulating material layer SPa of FIG. 10 may be patterned to form a spacer SP as illustrated in FIG. 11. The spacer SP may be located between adjacent light emitting areas PX1 and PX2. The spacer SP may be located in the non-light emitting area NLA located between the first light emitting area PX1 and the second light emitting area PX2 as illustrated in FIG. 11. The spacer SP may be located between the first light emitting layer EML1 and the second light emitting layer EML2. The spacer SP physically separates the first light emitting layer EML1 and the second light emitting layer EML2 and provides electrical insulation, preventing problems such as, for example, current leakage.

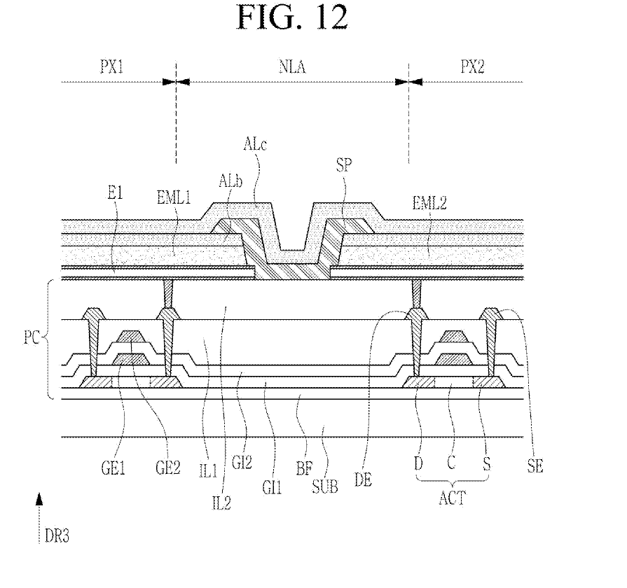

Next, referring to FIG. 12, a third metal material layer ALc overlapping the entire surface of the substrate SUB may be formed on the second metal material layer ALb and the spacer SP. The third metal material layer ALc may be continuously disposed over the first light emitting area PX1, the second light emitting area PX2, the third light emitting area, and the non-light emitting area NLA. The third metal material layer ALc may overlap with the second metal material layer ALb in the non-light emitting area NLA, with the spacer SP between the third metal material layer ALc and the second metal material layer ALb. The second metal material layer ALb and the third metal material layer ALc may contact each other in portions of the first light emitting area PX1, the second light emitting area PX2, and the non-light emitting area NLA.

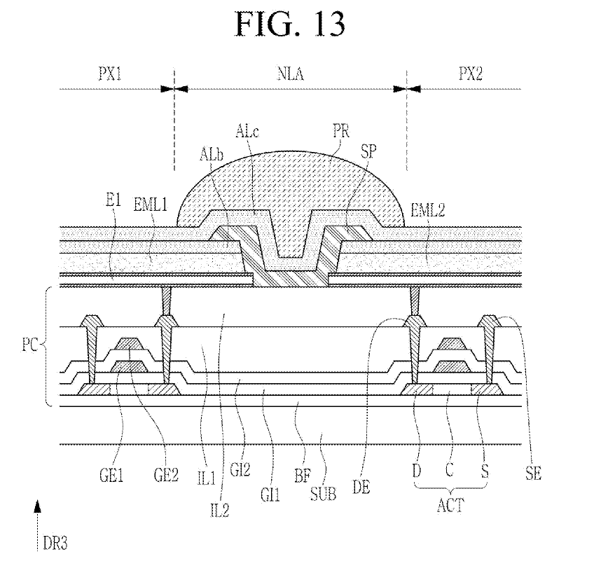

Then, as illustrated in FIG. 13, a photosensitive pattern PR is formed on the third metal material layer ALc. The photosensitive pattern PR may overlap with the spacer SP and cover adjacent portions of the spacer SP. The third metal material layer ALc may be etched using the photosensitive pattern PR as a mask.

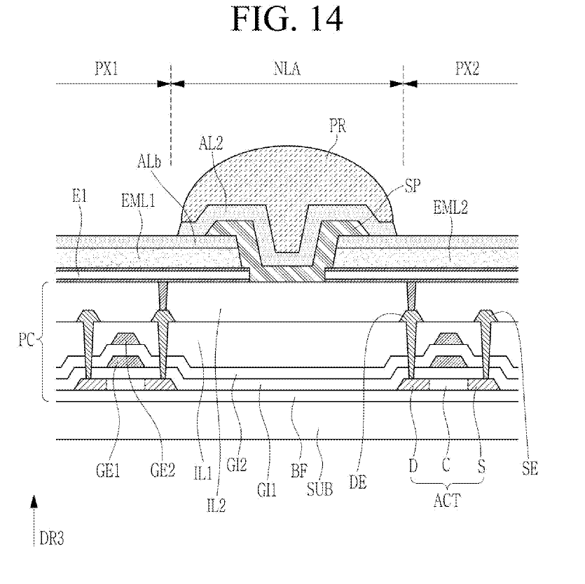

Thereafter, as illustrated in FIG. 14, a second auxiliary metal layer AL2 may be formed. The second auxiliary metal layer AL2 is formed by patterning the third metal material layer ALc illustrated in FIG. 13, and at this time, an etching process may be performed using the photosensitive pattern PR as a mask.

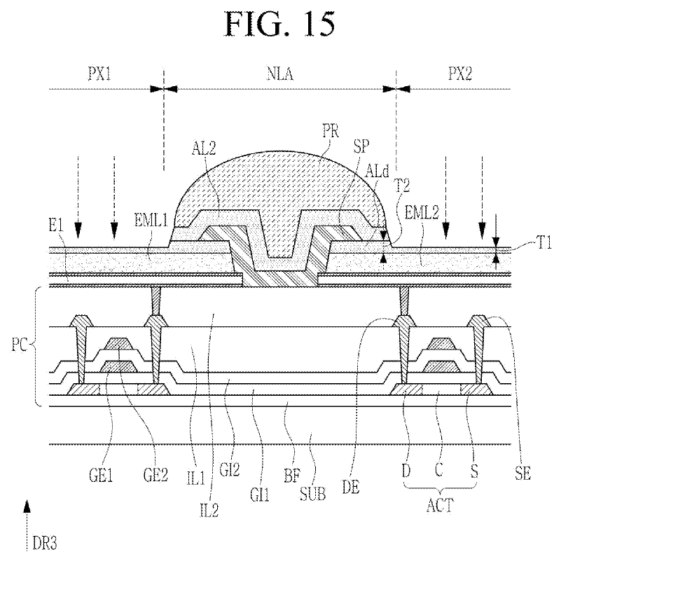

Then, the second metal material layer ALb may be additionally etched to form a fourth metal material layer ALd as illustrated in FIG. 15. The fourth metal material layer ALd may have a first thickness T1 in the first light emitting area PX1 and the second light emitting area PX2, and may have a second thickness T2 in the non-light emitting area NLA. The first thickness T1 may be smaller than the second thickness T2. In the etching process of FIG. 15, if the metal material layer overlapping with the light emitting areas PX1 and PX2 is completely removed, the light emitting layers EML1 and EML2 may be damaged. Therefore, in the etching process of FIG. 15, a portion of the exposed second metal material layer ALb may be etched, and not the entirety of the exposed second metal material.

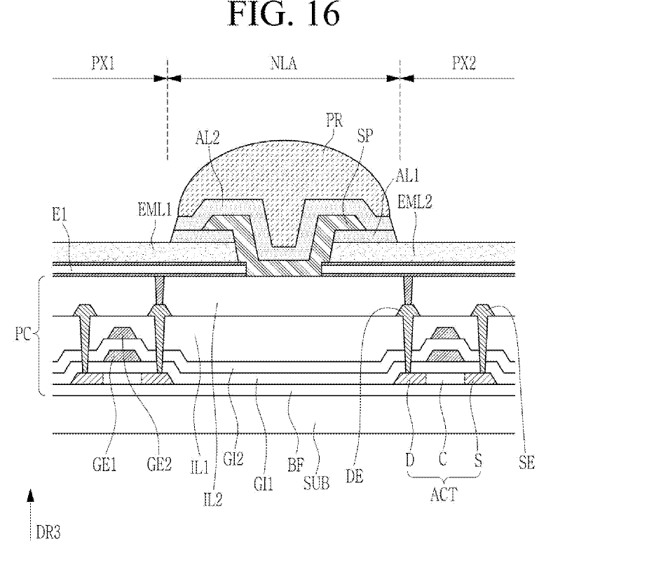

Next, as illustrated in FIG. 16, a first auxiliary metal layer AL1 may be formed. The first auxiliary metal layer AL1 of FIG. 16 may be formed by removing, from the fourth metal material layer ALd of FIG. 15, the portions of the fourth metal material layer ALd that are exposed by the photosensitive pattern PR. A portion of the fourth metal material layer ALd may be removed through a wet etching process, and for example, a diluted hydrogen fluoride (HF) solution may be used.

Because the first auxiliary metal layer AL1 and the second auxiliary metal layer AL2 are patterned using the same photosensitive pattern PR, they may have side surfaces having substantially the same inclination. The side surfaces of the first auxiliary metal layer AL1 and the second auxiliary metal layer AL2 may form substantially a surface.

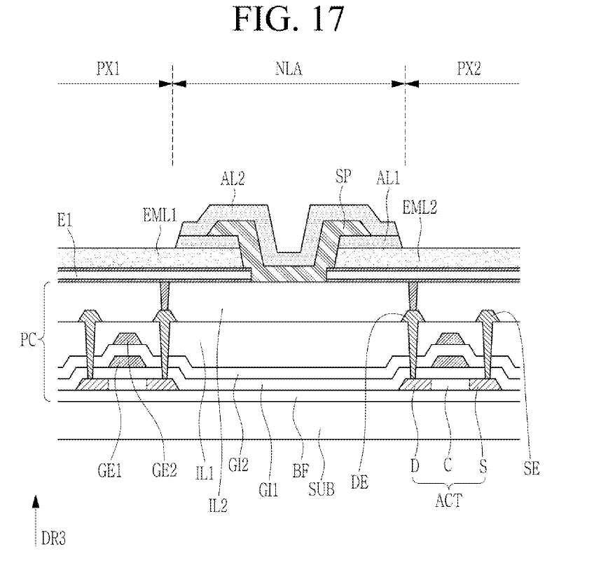

Then, the photosensitive pattern PR may be removed to provide a structure as illustrated in FIG. 17. After removing the photosensitive pattern PR, the substrate SUB may be dried in a vacuum state, and a second electrode and an encapsulation layer may be sequentially formed in a vacuum chamber. For a case in which the second electrode is formed on the entire surface of the substrate SUB, a display device having a form as illustrated in FIG. 6 may be provided.

A display device according to an embodiment may have a structure in which the first auxiliary metal layer and the second auxiliary metal layer include the same metal and contact each other at both ends. In particular, for a case in which the first auxiliary metal layer and the second auxiliary metal layer include titanium, the first auxiliary metal layer and the second auxiliary metal layer may be stably bonded due to excellent adhesion characteristics. In some aspects, for a case in which the first auxiliary metal layer and the second auxiliary metal layer include titanium, a stable process is possible with respect to the developer used in the patterning process, such that the reliability of the display device can be improved. In some aspects, because the first auxiliary metal layer and the second auxiliary metal layer are stably connected to the second electrode at the contact portion, a display device with improved reliability can be provided.

Although the embodiments of the present disclosure have been described in detail above, the scope of embodiments of the present disclosure are not limited thereto, and various modifications and improvements by those skilled in the art using the basic concept of the present disclosure defined in the following claims also fall in the scope of the present disclosure.

What is claimed is:

1. A display device comprising:
a substrate comprising a light emitting area and a non-light emitting area;
a transistor located in the light emitting area;
a first electrode electrically connected to the transistor;
a light emitting layer located on the first electrode;
a first auxiliary metal layer located on the light emitting layer and at an edge of the light emitting layer;
a second auxiliary metal layer located on the first auxiliary metal layer;
a spacer located between the first auxiliary metal layer and the second auxiliary metal layer; and
a second electrode located on the light emitting layer and the second auxiliary metal layer.

2. The display device of claim 1, wherein an end of the second auxiliary metal layer covers an edge of the light emitting layer.

3. The display device of claim 1, wherein an end of the spacer overlaps with an edge of the light emitting layer.

4. The display device of claim 1, wherein ends of the first auxiliary metal layer contact ends of the second auxiliary metal layer.

5. The display device of claim 4, wherein a portion of the spacer is located between the first auxiliary metal layer and the second auxiliary metal layer.

6. The display device of claim 5, wherein:
the display device further comprises an insulating layer located between the transistor and the first electrode, and
another portion of the spacer is located between the second auxiliary metal layer and the insulating layer.

7. The display device of claim 1, wherein the first auxiliary metal layer and the second auxiliary metal layer comprise the same metal.

8. The display device of claim 7, wherein the first auxiliary metal layer and the second auxiliary metal layer comprise titanium.

9. The display device of claim 1, wherein the spacer comprises an inorganic insulating material.

10. The display device of claim 1, wherein the spacer has a stepped shape toward the substrate in a cross-sectional view between adjacent first electrodes.

11. The display device of claim 10, wherein the second auxiliary metal layer has a stepped shape toward the substrate in the cross-sectional view between the adjacent first electrodes.

12. The display device of claim 1, wherein the spacer covers a side surface of the first auxiliary metal layer, a side surface of the light emitting layer, and a side surface of the first electrode.

13. The display device of claim 1, wherein a first end of the first auxiliary metal layer and a first end of the second auxiliary metal layer are aligned with each other.

14. The display device of claim 1, wherein a first end of the light emitting layer and a second end of the first auxiliary metal layer are aligned with each other.

15. An electronic device comprising a display device, the display device comprising:
a substrate comprising a light emitting area and a non-light emitting area;
a transistor located in the light emitting area;
a first electrode electrically connected to the transistor;
a light emitting layer located on the first electrode;
a first auxiliary metal layer located on the light emitting layer;
a second auxiliary metal layer located on the first auxiliary metal layer; and
a second electrode located on the light emitting layer and the second auxiliary metal layer,
wherein the second electrode contacts the first auxiliary metal layer and the second auxiliary metal layer.

16. The electronic device of claim 15, further comprising a spacer located between the first auxiliary metal layer and the second auxiliary metal layer.

17. The electronic device of claim 15, wherein the second electrode contacts a side surface of the first auxiliary metal layer, a side surface of the second auxiliary metal layer, and an upper surface of the second auxiliary metal layer.

18. The electronic device of claim 15, wherein an end of the first auxiliary metal layer and an end of the second auxiliary metal layer contact each other.

19. The electronic device of claim 15, wherein the first auxiliary metal layer and the second auxiliary metal layer comprise the same metal.

20. The electronic device of claim 15, wherein the second auxiliary metal layer overlaps with two adjacent first electrodes.
